(19) United States
(12) Patent Application Publication
(10) Pub. No.: US 2019/0013611 A1
(43) Pub. Date: Jan. 10, 2019

(54) ELECTRICAL CONNECTOR FOR CHARGING ELECTRIC STORAGE BATTERY CELLS

(71) Applicant: SOVEMA GROUP S.P.A., Villafranca di Verona (IT)

(72) Inventor: Luciano FERRARESE, Lavagno (IT)

(21) Appl. No.: 16/029,671

(22) Filed: Jul. 9, 2018

(30) Foreign Application Priority Data
Jul. 7, 2017 (IT) 102017000076921

(51) Int. Cl. H01R 13/24; H02J 7/00; H01R 13/512; G01R 31/36

(52) U.S. Cl. CPC H01R 13/2492; H02J 7/0045; H02J 7/0021; H01R 13/2471; H01R 2201/20; H01R 13/512; G01R 31/3696; G01R 31/3658; H01R 13/2421

(57) ABSTRACT

Electrical connector for an apparatus for charging electric storage battery cells, which comprises a bush power supplied by an electrical power source and provided with an end wall intended to abut against an electrode of a cell of an electric storage battery in order to power supply it. The electrical connector also comprises an electrical contacting element mounted inside the bush and provided with a plurality of pins which traverse corresponding through holes, electrically isolated, of the end wall of the bush in order to abut against the electrode of the cell so to carry out electrical measurements.

### FIELD OF APPLICATION

The present invention regards an electrical connector for charging electric storage battery cells according to the preamble of the main independent claim.

The present electrical connector is inserted in the industrial field of the production of electric storage batteries, which are well-known to be employed in many different applications, such as in the automotive field, or in uninterrupted power supply, in forklifts or in many other applications where it is necessary to have a storage of electrical energy.

The present electrical connector is employed in the plants and processes for charging electric storage batteries of any type and in particular lithium storage batteries. More in detail, the present electrical connector is intended to be employed in the final step of the production process of storage batteries, i.e. in the step of the charging thereof (formation) when, with suitable electrical power plants, a plurality of storage batteries are simultaneously subjected to controlled charging processes.

More particularly, the electrical connector in question is intended to be advantageously employed in automated charging plants where the plurality of connectors is automatically electrically brought into contact with a corresponding plurality of cells of the storage batteries for the execution of the aforesaid controlled charging processes.

### State of the Art

In the industrial field of production of electric storage batteries, it is known to charge a plurality of storage batteries simultaneously, controlling the charging steps with sensors and/or measurements that detect, for example, the response of the single cell of the storage battery to the electrical power supply.

As is known, lead storage batteries are power supplied in the step of formation with the cells in series and are only controlled overall at the final poles of the storage battery, while lithium storage batteries—the latter available with various chemical types (e.g. lithium iron phosphate, lithium iron disulfide, lithium manganese dioxide, lithium thionyl chloride, lithium polymers and still others)—are power supplied during the cell-by-cell formation, and thus the latter require being separately controlled both for safety reasons and to prevent for example phenomena of self-discharging in the single cells.

More in detail, the storage batteries are generally arranged in groups on a common base, on which an electrical manifold descends bearing, mounted thereon, a plurality of electrical connectors aimed to come into contact with the electrodes of the cells of the storage batteries in order to power them with the provided charge current.

In particular, for lithium storage batteries it is, as is known, during the formation step necessary to control the potential difference that is created between the electrodes of each cell, or better yet it is necessary to control the potential difference within the single cells for the entire load cycle and/or upon varying the charge current.

In the field of production of electric storage batteries, there is the particular need to overcome some drawbacks linked to the possibility that an oxide layer is generated on the surface of the electrodes of the cell or linked to an imperfect alignment of the electrode and of the connector which must come into contact in order to transmit the electrical power to the cell.

Electrical connectors are known which can be mounted on movable manifolds, having a relatively wide contact surface, such to overcome the abovementioned problems of electrode/connector alignment.

In addition, on the contact surface of the aforesaid connectors, a knurled surface is made with reliefs that have the object of breaking and penetrating the oxide layer so to be able to power the cell with the provided charge current.

The abovementioned electrical connectors are employed for achieving a control of the potential difference within the cell, through potential measurements carried out on the same electrical connectors in a distal position with respect to the contact surface between the connector and the electrode, through which the electrical power supply takes place.

In order to control the formation process, as mentioned above it is necessary to know the potential difference present at the ends of the electrodes of each cell, since this is indicative of the charging that occurred within the same.

The electrical connector of known type briefly described above has in practice proven that it does not lack drawbacks. An important drawback lies in the fact that the measurement of the potential difference is not carried out directly at the ends of the electrodes of each cell but on the connectors in order to power them with the charge current or more generally on the electrical power circuit. One such measurement, executed at points of the circuit that are not ends of the electrodes of the cell, is affected by an imprecision due to the fact that the voltage drop of the electrical power circuit connection—in particular due to the contact resistance with the electrode—is added to the potential difference that actually exists between the electrodes of the cell.

The contribution of this voltage drop on the measurement to be carried out is difficult to calculate with precision, in particular since it depends on the conditions on the electrical connection which in turn generally depend on the cleaning and on the degree of oxidation of the contacts between the electrode and the connector.

On the other hand, the power supply of the storage battery that brings the ends of a cell to an incorrect potential difference can lead, in particular with lithium cells, to self-discharges in the cell itself or to dangerous situations, actually bordering on the explosion of the cell itself.

In summary, the above-described connector is usually employed in apparatuses for forming lithium storage batteries comprising a movable manifold which bears, mounted thereon, a plurality of the aforesaid electrical connectors in order to bring them in contact with a plurality of electrodes of one or more side-by-side storage batteries, given that the contact surface of each single connector is wider than that of the electrode such to remedy possible misalignments. In addition, such contact surface of the connector is knurled in order to penetrate the possible surface oxide of the electrode.

More in detail, such apparatuses for forming storage batteries comprise a controlled electrical power supply adapted to supply the provided charge current and means for measuring the potential difference detected on the connectors for connecting to the electrodes of each cell.

Also known are electrical connectors, in particular employed in apparatuses for forming lithium storage batteries, which comprise a bush made of conductive material, and an electrical contacting element constituted by a pogo pin, it too made of conductive material mounted coaxially with the center of the bush.

More in detail, the bush is susceptible of being power supplied by an electrical power source, is provided with an internal cavity delimited by a substantially flat end wall, which is susceptible of abutting against, by means of a contact surface thereof, an electrode of a cell of an electric storage battery, in order to electrically charge it.

The pogo pin, in turn, is susceptible of being connected to measurement means and of abutting against, by means of a free end thereof, the electrode of the cell of the electric storage battery, in order to carry out electrical measurements, in particular for measuring the potential difference at the ends of the electrodes of the cell.

More in detail, the pogo pin, employed in the apparatuses for charging the electric storage batteries, usually has cylindrical form, and is pushed by a spring projecting from the contact surface of the electrical connector such that it can elastically abut against the surface of the electrode of a cell. The pogo pin is composed of a first portion intended to electrically contact the electrode of a cell, and a second portion connected to the measurement means. The two portions are maintained in mechanical and electrical connection with each other by the abovementioned spring which thus is interposed between the two portions.

Electrical connectors are known, characterized in that they have a contact surface on which one or more pogo pins are present; each of these pogo pins is slidable against the action of the aforesaid spring.

Nevertheless, also this known electrical connector embodiment has several drawbacks.

A first drawback is linked to the poor mechanical strength of the pogo pin. Indeed, in practice it is frequently deformed following impact and/or pressures imperfectly oriented along the longitudinal axis of the pogo pin itself.

A second drawback is linked to the misalignment that can occur between the contact surface of the connector and the electrode of the cell due to possible deformations. Such misalignment can lead to the lack of contact between the pogo pin and the electrode with consequent error of measurement of the potential difference.

A third drawback is connected to the imprecision of the electrical measurement of the potential difference due to the use of the pogo pin. The measurement means in fact provide for detecting the passage of small current through the spring of the pogo pin.

Said spring is constituted by a wire which has high resistance, above all due to its reduced section. It follows that, also in this case, a contribution of potential drop is present that is hard to estimate and which comes to be added to the potential difference actually present between the electrodes of the electrical cell, which must be measured with precision.

Therefore, the measurement that results is not very accurate and in the end the cell charging process results hard to control and thus potentially dangerous, given that the cell could be subjected to a potential difference different from that required for a correct charging process.

In addition, oxide layers could be created on the pogo pins that cannot be mechanically removed with ease, e.g. by means of brushing, due to the mechanical weakness of the pogo pin that is currently used.

The document KR 20030007279 describes a probe of known type for executing tests on lithium batteries, which comprises a support head provided with an end wall on which a front opening is made with cross form. In such front opening, a contacting element is slidably inserted that is susceptible of contacting the terminal of the battery in order to carry out electrical measurements. More in detail, the contacting element comprises a support base with cross form bearing, mounted thereon, a plurality of contact tips adapted to project beyond the end wall of the support head in order to contact the terminal of the battery. The probe described in the document KR 20030007279 has a reduced contact surface of the support head on the battery due to the front opening of the end wall thereof, as well as a limited contact zone of the tips of the contacting element since the position of such tips is located within the aforesaid front opening.

### PRESENTATION OF THE INVENTION

In this situation, the problem underlying the present invention is therefore that of overcoming the drawbacks of the above-mentioned prior art, by providing an electrical connector for charging electric storage battery cells which allows carrying out precise electrical measurements in the cell subjected to load cycle.

Another object of the present invention is to provide an electrical connector for charging electric storage battery cells, which is mechanically strong.

Another object of the present invention is to provide an electrical connector for charging electric storage battery cells, which is capable of compensating for imprecise positioning of the storage battery or variations of the centering of the electrodes following expansions of the cell.

Another object of the present invention is to provide an electrical connector for charging electric storage battery cells, which is simple to produce and easy to maintain.

Another object of the present invention is to provide an electrical connector for charging electric storage battery cells, which is safe and entirely reliable in operation.

Such problems are resolved through an electrical connector for an apparatus for charging electric storage battery cells, which comprises a bush made of conductive material, susceptible of being power supplied by an electrical power source, and provided with an internal cavity. Such internal cavity is delimited by a substantially flat end wall. The wall is susceptible of abutting against, by means of a contact surface thereof, an electrode of an electric storage battery, in order to electrically charge it. The electrical connector also comprises at least one electrical contacting element made of conductive material, such as copper. This contacting element is mounted inside the bush and can be connected to a measuring device. Such contacting element can abut against, by means of a free end thereof, the electrode of the electric storage battery, in order to carry out electrical measurements on the storage battery.

According to the invention, the electrical connector is characterized in that the electrical contacting element comprises a common base electrically connected to an electrical measurement cable, susceptible of being connected to the measuring device. The contacting element also comprises a plurality of pins, which are extended starting parallel to each other from said common base, and traverse a corresponding plurality of through holes obtained on said end wall. The pins can project, outside the bush, with a free end thereof. An electrical isolation system is also present, which is housed within the cavity of the bush in order to electrically isolate the bush from the electrical contacting element.

Due to this connector, it is possible to control the process of charging electrical cells of electric storage batteries, increasing the reliability of the process.

In addition, this connector is stronger and its maintenance is simple and inexpensive with respect to the connector with a single pogo pin.

### BRIEF DESCRIPTION OF THE DRAWINGS

The technical characteristics of the invention, according to the aforesaid objects, can be clearly seen from the contents of the below-reported claims and the advantages thereof will be more evident in the following detailed description, made with reference to the enclosed drawings which represent a merely exemplifying and non-limiting embodiment of the invention, in which:

FIG. 1 shows an axonometric view of an electrical connector for charging electric storage battery cells according to the present invention;

FIG. 2 shows a side view of the electrical connector of FIG. 1, according to the present invention;

FIG. 3 shows a longitudinal section view, made along the trace of FIG. 2, of the electrical connector according to the invention;

FIG. 4 shows an axonometric front view of a detail of the electrical connector according to the present invention, relative to a bush;

FIG. 5 shows a longitudinal section view, made along the trace V-V of FIG. 4, of the bush of the electrical connector according to the invention;

FIG. 6 shows a support structure of an apparatus for charging electric storage battery cells, on which a plurality of electrical connectors according to the present invention are mounted.

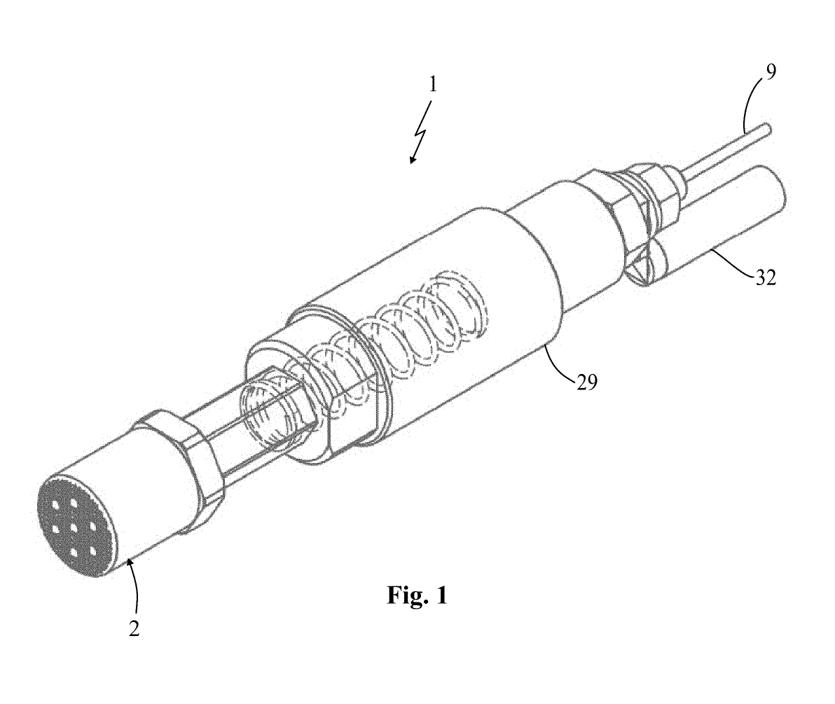

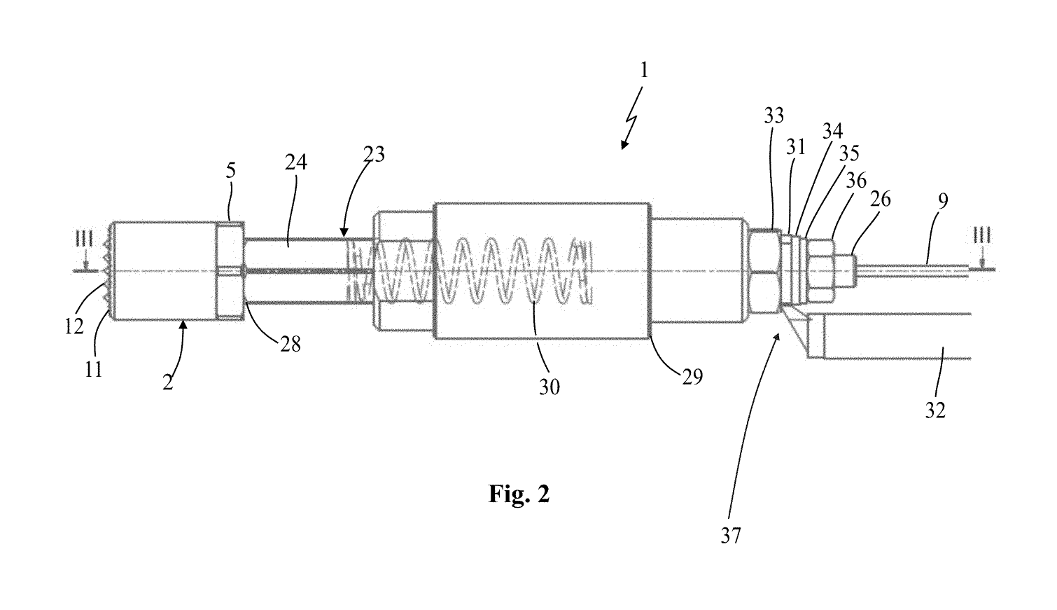

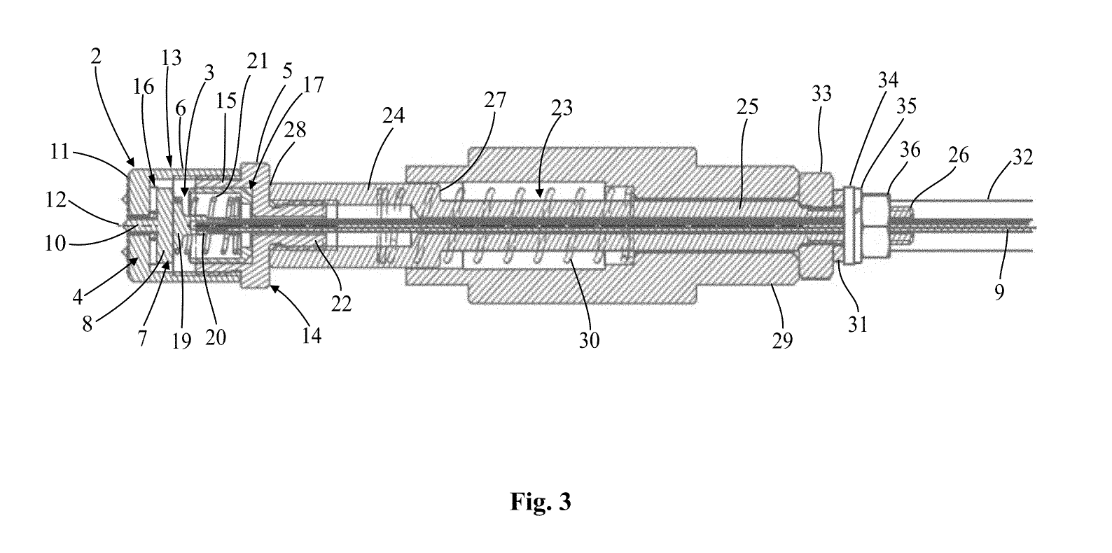

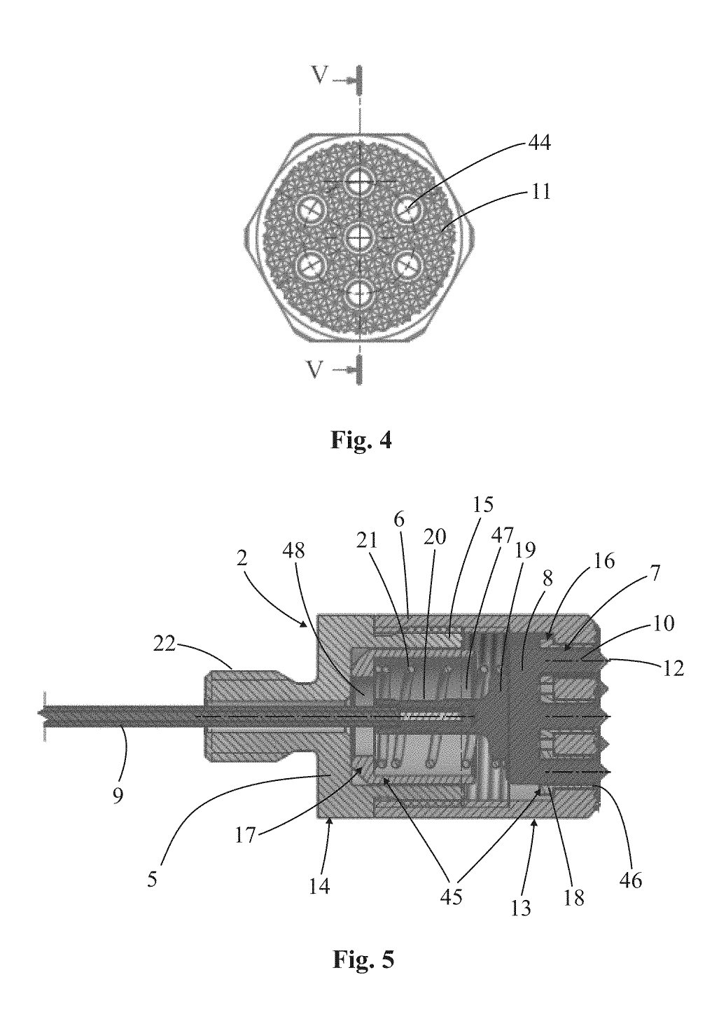

### DETAILED DESCRIPTION OF A PREFERRED EMBODIMENT

With reference to the enclosed drawings, reference number 1 overall indicates an electrical connector for charging electric storage battery cells, object of the present invention.

Such electrical connector 1 is intended to be advantageously employed in an apparatus for charging cells for the many different types of storage batteries, such as lead storage batteries, nickel storage batteries (nickel-cadmium, nickel-hydride metal . . . ) and lithium storage batteries.

In accordance with the embodiment illustrated in the enclosed figures, the connector is particularly intended for charging cells of storage batteries of lithium type, the latter available with different chemical types such as lithium iron phosphate, lithium iron disulfide, lithium manganese dioxide, lithium thionyl chloride, lithium polymers and still other types.

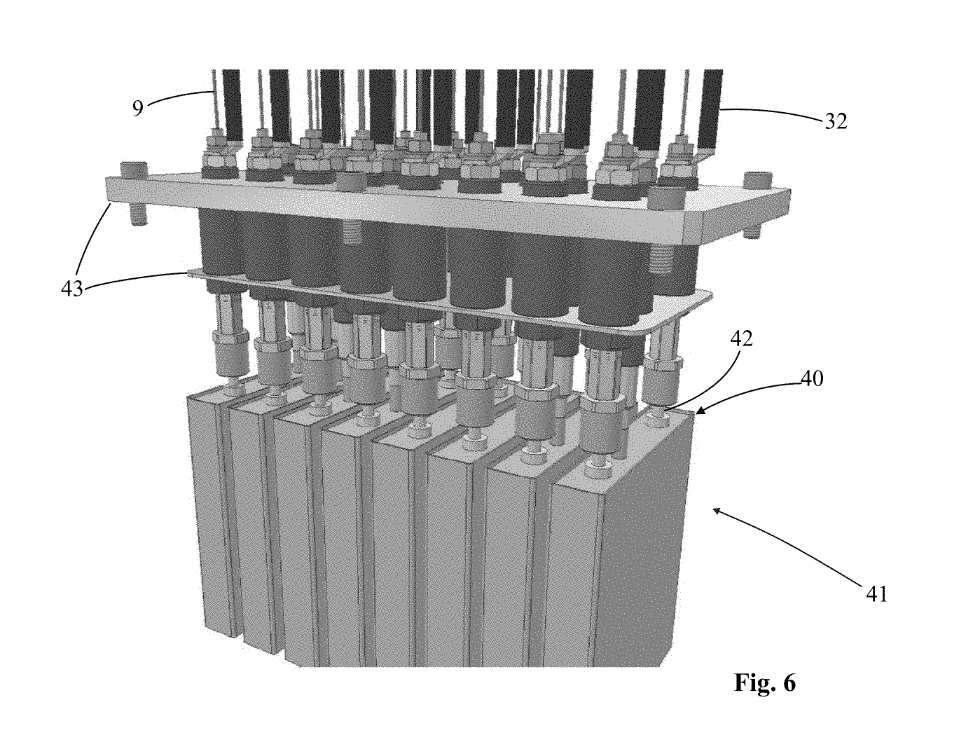

This electrical connector 1 can be advantageously mounted in a position contiguous to a plurality of equivalent connectors on a common support structure indicated in FIG. 6 with reference number 43. Such support structure 43 is movable with respect to the storage battery or to a plurality of side-by-side storage batteries, in order to be able to advantageously charge the storage batteries and carry out electrical measurements on the cells of the same storage batteries.

The electrical connector 1, object of the present invention, comprises a bush 2 made of conductive material, such as copper, which is susceptible of being power supplied by an electrical power source of the apparatus for charging the cells.

The bush 2 preferably has a cylindrical shape and at its interior delimits a cavity 3, also advantageously with cylindrical form. Such internal cavity 3 is, more particularly, delimited by several walls of the bush 2 and more precisely by: a substantially flat end wall 4, a bottom wall 5 and a lateral wall 6 which will be better specified hereinbelow.

The end wall 4 of the bush 3 has a contact surface 11, which is intended to abut against an electrode 42 of a cell 40 of an electric storage battery 41, in order to charge the cell 40 itself. Such contact surface 11 of the bush 3 can be advantageously knurled in order to improve the electrical contact with the electrode 42, by traversing the oxide layers that may have formed on the electrode 42 itself.

In particular, the bush 2 is advantageously formed by two elements: a first shaped element 13 and a second shaped element 14 that are mechanically coupled together.

The first shaped element 13 has substantially U shape and comprises a wall which acts as end wall of the bush and which hereinbelow will be termed end wall 4, and a first lateral wall 6, which is connected by means of a first bend to the end wall 4.

The second shaped element 14 is provided with a U-shaped portion, which comprises a bottom wall 5 and a second lateral wall 15. Also this second lateral wall 15, like the preceding, is connected by means of a second bend to the other wall, or in this case to the bottom wall 5.

The mechanical coupling between the two shaped elements 13, 14 is attained due to a screwing engagement between the first lateral wall 6 of the first shaped element 13 and the second lateral wall 15 of the second shaped element 14.

In accordance with the preferred embodiment illustrated in the enclosed figures, such second shaped element 14 comprises a neck portion 22, which is advantageously threaded. Such neck portion 22 departs from the bottom wall 5, being extended in a direction opposite the second lateral wall 15 of the second shaped element 14.

These shaped elements 13 and 14 delimit the cavity 3 of the bush 2 between them, in accordance with the above-described embodiment.

Within the cavity 3 of the bush 2, an electrical contacting element 7 is positioned, it too constructed with a conductive material, such as copper. The electrical contacting element 7 has a free end 12, which comes into contact with the electrode of the cell of the storage battery, and more precisely with its upper terminal face. Such electrical contacting element 7 is intended to be connected to a measurement equipment of the apparatus for charging the cells, in order to carry out electrical measurements inside the cell, in particular relative to the charge state reached by the cell, or voltage state reached at the ends of its electrodes 42.

According to the idea underlying the present invention, the electrical contacting element 7 comprises a common base 8, which is electrically connected to a cable 9 in turn intended to be connected to the measurement equipment. Starting from the common base 8, a plurality of pins 10 are extended parallel to each other, and such pins 10 traverse a corresponding plurality of through holes 44. The latter are made on the end wall 4 of the bush 2. More in detail, the pins 10 project from the contact surface 11 of the end wall 4 with their free end 12. In addition, still according to the idea underlying the present invention, also an electrical isolation system 45 is present within the cavity 3 of the bush 2, and such system 45 electrically isolates the electrical contacting element 7 from the bush 2.

Due to the aforesaid characteristics, the electrical connector 1, object of the present invention, allows recharging electric storage battery cells and, simultaneously, controlling electrical parameters such as the potential difference at the ends of the electrodes of each single cell, as well as allowing a simple and inexpensive maintenance.

Preferably, the contacting element 7 is provided with a tube 20 which is extended from the common base 8 thereof in opposite direction with respect to the pins 10. This tube 20 is internally hollow in order to be able to advantageously receive the measurement cable 9, which is placed in electrical contact with the tube 20, for example by means of a crimping process.

In accordance with the embodiment illustrated in the enclosed figures, the isolation system 45 comprises a first isolation body 16 and a second isolation body 17. The first isolation body 16 is provided with a base element 18, interposed between the common base 8 of the contacting element 7 and the internal face of the end wall 4 of the bush 2, and with a plurality of tubular elements 46.

These tubular elements 46 are connected at one end thereof to the base element 18 and are housed in the through holes 44 of the end wall 4, in order to isolate the pins 10 of the contacting element 7 from the bush 2, i.e. in order to avoid such pins 10 from coming into contact with the end wall 4 of the bush 2.

The second isolation body 17 is in turn advantageously provided with a first opening 47, directed towards the end wall 4 and traversed by the tube 20 of the electrical contacting element 7, and a second opening 48 directed towards a bottom wall 5 of the cavity 3.

This second opening 48 faces the end wall 4 and is traversed by the electrical measurement cable 9. The second isolation body 17 comprises an annular portion placed to cover the bottom wall 5 of the cavity 3, and preferably also a lateral portion, which covers the lateral wall 15 of the second shaped element 14.

In addition to that stated above, the electrical connector 1 comprises a first elastic element 21, which is advantageously housed within the cavity 3 of the bush 2 and acts on the electrical contacting element 7 in order to push the free ends 12 of the pins 10 towards the contact surface 11.

In the embodiment represented in the enclosed figures, the aforesaid first elastic element 21 is preferably constituted by a first helical spring 21, which is mounted coaxially with the electrical measurement cable 9.

More in detail, the first helical spring 21 abuts, at a first end, against the annular portion of the second isolation body 17, and at a second end against the common base 8 of the electrical contacting element 7.

In particular, the second end of the first helical spring 21 is engaged in a retention relationship on a projection 19 that departs from the common base 8 of the electrical contacting element 7, in a direction opposite that of the pins 10 and which is then advantageously extended in such direction by the abovementioned tube 20 for the fixing of the measurement cable 9.

Additionally, the electrical connector 1 comprises an elongated spacer body 23 composed of a first externally threaded terminal portion 26, a second central portion 25 and a third terminal portion with greater section 24. In particular, the second central portion 25 is extended starting from a shoulder 27 (narrowing) which delimits it from the third terminal portion with greater section 24, up to the start of the first threaded terminal portion 26.

In turn, the third terminal portion with greater section 24 is extended from the shoulder 27 up to an end section 28 of the spacer 23 directed towards the bush 2. Such elongated spacer 23 is advantageously provided with a through cavity in order to allow the internal passage of the measurement cable 9. In addition, the through cavity of the elongated spacer 23 has, at the third terminal portion with greater section 24, an enlargement that defines a central hole, which is advantageously threaded, at least at a first section directed towards the bush 2, in order to be able to receive the neck portion 22 in a screwing relationship and hence mechanical retention relationship; such neck portion 22, suitably threaded, is part of the second shaped element 14 of the bush 2. More generally, the neck portion 22 is fixed to the elongated spacer 23 with fixing means that can be different from a screw/nut screw coupling indicated above where, without departing from the protective scope of the present patent, the term fixed must indicate any one form of mechanical coupling between the elongated spacer 23 and the bush 2. The same term must also include the embodiment that provides for making elongated spacer 23 integral with the second shaped element 14 of the bush 2.

Advantageously, the electrical connector 1 also comprises a hollow sleeve 29 which is externally mounted with respect to the spacer 23, in a manner such that the spacer 23 can advantageously slide within the sleeve 29, against the action of a second elastic element 30.

These second elastic element 30 is interposed between the spacer 23 and the sleeve 29 and more particularly between the shoulder 27 of the spacer 23 and a second shoulder of the sleeve 29. The second elastic element is, in this embodiment, advantageously constituted by a second helical spring 30.

The electrical connector 1 advantageously also comprises a connection clamp 37 for an electrical power cable 32. More in detail, on the first externally threaded terminal portion 26, a square washer 31 is housed that is made of conductive material, such as copper or steel. The square washer 31 is connected to the electrical power cable 32, which carries the charge current for the cell of the storage battery, and is advantageously fastened in position by a nut-lock nut system. In particular, a nut 33 is abutted against a first side of the square washer 31, such nut 33 advantageously constituted by a conductive material, while the second side of the washer, opposite the first, abuts against a flat washer 34. Such flat washer 34 is side-by-side an elastic washer 35, which is in contact with the flat washer 34 on a first side while on a second side, opposite the first, it is in contact with a lock nut 36.

The invention thus conceived therefore attains the pre-established objects.

In particular, the claimed configuration, in which the pins 10 of the electrical contacting element 7 are inserted in corresponding through holes 44 of the end wall 4 of the bush 2, allows uniformly distributing the pins 10 over the area of the end wall 4 for an optimal detection of the measurements, simultaneously obtaining a high contact surface area 11 of the latter for charging the electric storage battery 41.

1. An electrical connector (1) for an apparatus for charging electric storage battery cells, said electrical connector (1) comprising:
a bush (2) which is made of conductive material and is susceptible of being power supplied by an electrical power source; wherein said bush (2) is provided with an internal cavity (3) and with an end wall (4); wherein said end wall (4) is provided with an internal face, which delimits said internal cavity (3), and with a contact surface (11), which is susceptible of abutting against an electrode (42) of a cell (40) of an electric storage battery (41), in order to electrically charge said storage battery (41);
an electrical contacting element (7) which is made of conductive material, is mounted in the internal cavity (3) of said bush (2), is susceptible of being connected to a measurement equipment, and is susceptible of abutting against the electrode (42) of said cell (40), in order to carry out electrical measurements;
wherein the end wall (4) of said bush (2) is provided with a plurality of through holes (44);
wherein said electrical contacting element (7) comprises:
a common base (8) configured to be electrically connected to a cable (9) of said measurement equipment;
a plurality of pins (10), which are extended, parallel to each other, starting from said common base (8), traverse corresponding said through holes (44) of said end wall (4), and are provided with corresponding free ends (12) which are susceptible of projecting from the contact surface (11) of said end wall (4) in order to abut against the electrode (42) of said cell (40);
an electrical isolation system (45), which is housed within the internal cavity (3) of said bush (2) in order to electrically isolate said bush (2) from said electrical contacting element (7);
wherein said electrical connector (1) comprises a first elastic element (21), which acts on said electrical contacting element (7) for pushing the free ends (12) of said pins (10) outside the contact surface (11) of said end wall (4);
wherein said electrical isolation system (45) comprises a first isolation body (16) comprising:
a base element (18) interposed between the common base (8) of said contacting element (7) and the internal face of the end wall (4) of said bush (2); and
a plurality of tubular elements (46) which are connected to said base element (18) and are inserted in the through holes (44) of said end wall (4) in order to isolate said pins (10) from said bush (2).

2. The electrical connector (1) of claim 1, wherein said bush (2) comprises a first shaped element (13) and a second shaped element (14);
wherein said first shaped element (13) has a substantially U shape and comprises said end wall (4) and a first lateral wall (6) connected by means of a first bend to said end wall (4),
wherein said second shaped element (14) is provided with a U-shaped portion, which comprises a bottom wall (5) and a second lateral wall (15) connected by means of a second bend to said bottom wall (5);
wherein the first lateral wall (6) of said first shaped element (13) is mechanically connected in a screwing relationship to the second lateral wall (15) of said second shaped element (14);
wherein said shaped first shaped element (13) and said second shaped element (14) delimit, between them, the internal cavity (3) of said bush (2).

3. The electrical connector (1) of claim 2, wherein said electrical isolation system (45) comprises a second isolation body (17), which is provided:
with a first opening (47) directed towards said end wall (4) and traversed by said electrical contacting element (7), and
with a second opening (48) directed towards said bottom wall (5), facing said end wall (4) and traversed by the cable (9) of said measurement equipment;
wherein said second isolation body (17) at least partially covers an internal surface of the internal cavity (3) of said bush (2) and comprises an annular portion placed to cover the bottom wall (5) of said second shaped element (14) and a lateral portion to cover the lateral wall (15) of said second shaped element (14).

4. The electrical connector (1) of claim 1, wherein said first elastic element (21) is at least partially housed within the internal cavity (3) of said bush (2).

5. The electrical connector (1) of claim 3, wherein said first elastic element (21) is housed within the internal cavity (3) of said bush (2);
wherein said first elastic element (21) comprises a helical spring mounted coaxially with said cable (9) and provided with a first end, which abuts against the annular portion of said second isolation body (17), and with a second end, which abuts against the common base (8) of said electrical contacting element (7).

6. The electrical connector (1) of claim 5, wherein the second end of said helical spring is engaged in a retention relationship with a projection (19) that departs from said common base (8) in a direction opposite said pins (10).

7. The electrical connector (1) of claim 2, wherein said second shaped element (14) comprises a neck portion (22);
wherein said electrical connector (1) also comprises:
an elongated spacer body (23) fixed to said neck portion (22);
a hollow sleeve (29) mounted outside said spacer body (23);
a second elastic element (30) acting on said spacer body (23) which is susceptible of sliding within said hollow sleeve (29) against the action of said second elastic element (30).

8. The electrical connector (1) of claim 7, wherein said second elastic element (30) is interposed between a first shoulder (27) of said spacer body (23) and a second shoulder of said hollow sleeve (29).

9. The electrical connector (1) of claim 1, wherein said electrical connector (1) is mountable in a position contiguous to and together with a plurality of equivalent electrical connectors (1) on a support structure (43) that is movable with respect to said electric storage battery (41) or with respect to multiple side-by-side electric storage batteries (41) for charging said electric storage batteries (41) and carrying out electrical measurements on the cells (40) of said electric storage batteries (41).
